(19) United States
(12) Patent Application Publication
(10) Pub. No.: US 2011/0223401 A1
(43) Pub. Date: Sep. 15, 2011

(54) FIBROUS PRODUCT HAVING A BARRIER LAYER AND METHOD OF PRODUCING THE SAME

(75) Inventors: Ali Harlin, Vtt (FI); Eero Iiskola, Lieksa (FI); Mika Vähä-Nissi, Espoo (FI); Terhi Hirvikorpi, Espoo (FI); Tuomas Mustonen, Vtt (FI)

(73) Assignee: VALTION TEKNILLINEN TUTKIMUSKESKUS, Espoo (FI)

(21) Appl. No.: 13/122,341

(22) PCT Filed: Oct. 1, 2009
(86) PCT No.: PCT/FI2009/050786

§ 371 Date: May 26, 2011

(30) Foreign Application Priority Data
Oct. 3, 2008 (FI) 20085937

(51) Int. Cl. B32B 7/02; B32B 5/00; C23C 16/44; C23C 16/513; C23C 16/06; C23C 16/22

(52) U.S. Cl. 428/216; 428/336; 427/255.24; 427/569; 427/250

(57) ABSTRACT

The invention relates to barrier products and a method for the manufacture thereof. The product comprises a fibrous substrate, a coating layer on at least one surface of the fibrous substrate, and a barrier applied on the coating layer, comprising a thin film with a thickness of less than about 1 micrometer and capable of providing barrier properties to the fibrous product. According to the invention, the coating layer comprises biopolymer, which have been found to be suitable for atomic layer deposition of thin barrier films comprising e.g. metal oxide. Improved oxygen, water vapour and aroma barrier properties can be achieved by the invention for papers and paperboards for packaging purposes.

### BACKGROUND OF THE INVENTION

1. Field of the Invention

The present invention relates to fibrous products having barrier layers. In particular, the present invention concerns substrates having barrier layers formed by thin films and the production thereof.

2. Description of Related Art

Packaging materials, such as paper, solid bleached board (SBB), folding box board (FBB), recycled chipboard, and liners for corrugated materials, can be coated or treated with various barrier substances in order to provide effective protection against undesirable effects caused by external sources such as light, oxygen, moisture, aromas, or heat to the product the package contains. In addition, the purpose of the barrier substance is to prevent leakage and absorption of the product and its substances to the packaging material, meaning grease, moisture or aromas. The majority of barrier coating applications consist of polymers applied as relatively thick layers onto the base material.

In addition to product protection, selecting the most suitable coating and baseboard combination saves material, improves and simplifies processability (such as printing, converting performance), visual quality (such as attractiveness, brightness), end-use performance (such as sealability and peelability), and reduces waste.

Polyolefin barriers, typically LDPE, HDPE and PP coatings, give good moisture protection. They are widely used in packages where good liquid tightness and moisture protection are required, typically for beverages, cereals, frozen food and ice cream.

High barrier polymer coatings provide excellent light, oxygen and moisture protection. These multilayer EVOH and PA coatings can be made greaseproof and both light and oxygen tight. High barrier silver and aluminium coatings have an additional metallic layer to provide maximum protection against light.

High barrier polymer coatings are used in long shelf life packages of sensitive products such as coffee, spices, beverages, cereals, and chocolate. They are also used to pack non-food products such as liquid detergents, fabric softeners, etc.

Performance barriers provide both barrier and other additional functions. Typical examples are PET coatings, which provide heat resistance together with excellent grease barrier and good WVTR (=Water Vapour Transmission Rate) properties for ovenable trays and reheatable packages. PBT polymers are similar to PET in their functions, but enhanced with excellent release properties.

WO 1999/015711 discloses a substrate having a SiO₂ barrier layer applied thereon by the One Atmosphere Uniform Glow Discharge Plasma (OAUGDP) method, which belongs to the family of plasma chemical vapour deposition (CVD) methods. The substrate may be a paper coated with LDPE (low density polyethylene). A drawback of the process is that it is physical in nature and thus the process control and scale-up to larger area substrates is complicated. The process involves a plasma degradation of silicon precursor that is precipitated from reactor atmosphere onto the surface. There are no examples in the publication how the barrier properties change. However, it is known that it is difficult to produce pinhole-free and dense layers using plasma CVD, in particular with low layer thicknesses.

As discussed in Paperi ja puu 2006, vol. 88, no. 2, pp. 115-120, environmental demands set new pressure to packaging materials. Biodegradable coating is an alternative for polyethylene in barrier boards. In this experimental study boards with biodegradable coatings were compared with uncoated and LDPE coated board by evaluating their biodegradation potential and also considering their potential in waste reduction through recycling and incineration processes. The biodegradation potential was studied in a soil burial test. The results demonstrate that under tropical conditions uncoated paperboard samples degrade fast (in less than two months) when there is a good contact with the soil that contains nutrients, organic material and has a suitable pH. The biodegradable coating materials degrade but at a considerably slower rate than the fibrous base board. The degradation of the coating layer take place very locally, possibly initiating at some local grooves, pores or cracks in the coating. When the microorganisms reach the base board then the degradation proceeds in the base board at an accelerated pace. The biodegradability of coating materials gives an additional option in waste management. However, the high water vapour transmission values of these biodegradable materials mean that thicker coating layers are needed to fulfil the barrier requirement in packaging applications, and this—together with the higher price of biodegradable polymers—may escalate the production costs. The barrier coated boards, without exception, were found to be recyclable; and after recycling the fiber and paper quality properties were comparable with those of the uncoated sample. But the heat value of the polyethylene coating was higher than heat values of the biodegradable barrier coatings. These facts imply that in short term the biodegradable coatings will have difficulties to find profitable applications in paperboard packages, especially if legislation is emphasizing the recycling and incineration options in waste treatment. However, developments in biopolymer science and in barrier coating formulations during the last years together with the increasing oil price promise more effective coating structures and better price competitiveness in the future for the biodegradable barrier coatings. In addition, according to European Bioplastics, biopolymers enable carbon dioxide savings of up to 30-80% compared to conventional plastics, depending on the product and application. Multiple projects focusing on new bio-based packaging applications have been funded by the EU, such as SUSTAINPACK and Flexpakrenew.

Many foods require specific atmospheric conditions to sustain their freshness and overall quality during storage. Hence, increasing amounts of our foods are being packed in protective atmosphere with a specific mixture of gases ensuring optimum quality and safety of the food product in question. To ensure a constant gas composition inside the package, the packaging material needs to have certain gas barriers. In most packaging applications the gas mixture inside the package consists of carbon dioxide, oxygen and nitrogen or combinations hereof. Literature provides a vast amount of information on the barrier properties of biobased materials using mineral oil based polymer materials as benchmarks.

It is expected that paper will remain an important biobased packaging material. Paper and board materials have excellent mechanical properties, however, the gas permeability properties as such are far too high for many food packaging applications. The hydrophilic nature of the paper-based materials is a major challenge of these materials when packaging moist foods. To date, the paper-based materials have been coated with a layer of synthetic plastic which has provided the materials with the required gas barrier and water resistance.

N. Gontard and S. Guilbert discussed in Food Packaging and Preservation, 1999, that biopolymers have limited barrier especially with water and water vapour. Water causes a substantial drop in the glass transition temperature of biopolymers which makes biopolymer packaging moisture-sensitive. For example, the biodegradable paper sheet disclosed in JP 2003013391, which discloses the features of the preambles of the independent claims, utilizes a biopolymer layer on a paper. A somewhat similar structure is disclosed in JP 2004175397.

### SUMMARY OF THE INVENTION

It is an aim of the present invention to eliminate at least a part of the problems relating to the known art. In particular, it is an aim of the invention to provide a novel and more environmentally friendly material suitable for demanding packaging applications.

It is also an aim to provide a novel method for producing the present material.

The aims are achieved by the invention as defined in the independent claims. Thus, the invention provides a polymer-coated fibrous substrate, such as paper or board, having at least one surface and exhibiting a barrier layer on said surface, wherein said barrier layer comprises a thin film with a thickness of less than about 1 micrometer and is capable of providing barrier properties to said substrate. In particular, barrier is capable of decreasing the water vapour, gas, and/or grease permeability of the product. Preferably, the barrier layer is inorganic or comprises at least one inorganic sub-layer and is deposited on the coated substrate by the atomic layer deposition (ALD) method.

According to one embodiment the substrate is a paper or board suitable for packaging applications or the like special applications. In particular, the product may be in the form of a package or a packaging blank or a part of a package, such as an inside pouch. A potential application area for such products is the packaging of consumer goods such as food.

According to a preferred embodiment, the polymeric coating of the substrate comprises biopolymer, in particular biodegradable polymer. Thus, the invention improves the barrier properties of fiber substrate like paper or paper board coated with layer or multiple layers of biopolymer-containing material, such as a single biopolymer, a blend of biopolymers, or blend of biopolymers and synthetic non-biobased polymers. Biopolymers, as to be understood within this document, include
polymers directly extracted from biomass (Category 1),
polymers produced by classical chemical synthesis from biobased monomers (Category 2), or
polymers produced directly by natural or genetically modified organisms (Category 3).

In addition, synthetic biodegradable polymers are included. Examples of the biopolymers which may be used include poly(hydroxyalkaonates) (PHA) including poly(hydroxybutyrate) and various copolymers, biodegradable polyesters including polylactic acid (PLA), poly(butylene succinate) (PBS), polycaprolactone (PCL) and other aliphatic/aromatic biodegradable copolyesters, bio-based polyurethanes and polyamides, various animal and plant proteins, polyphenols including tannin and lignin, polysaccharides including starch, chitosan, cellulose and hemicelluloses, lipids , and their derivatives, poly(vinyl alcohol), poly(ester carbonate), polyanhydrides and polyphosphazenes. Polysaccharides, their derivatives and blends with other biopolymers, for example, can provide coatings with relatively good gas barrier, but they are moisture sensitive materials. Today, PLA and blends of PLA and other biopolymers are used as coatings providing only moderate barrier properties.

In particular, the thin inorganic barrier layer may comprise inorganic oxides in layers. Such structure can be manufactured thin enough by atomic layer deposition (ALD) so as to enable recycling of the fiber based material without separation of barrier when recovered either as energy or material and fibre recycled for use in paper and board. Instead or in addition to inorganic material, the barrier layer may comprise organic atomic layer depositable material(s).

The ALD process used is preferably continuous. The thin film barrier layer is formed in several depositions carried out in series so as to form thicker films of one or more materials on well prepared coated surface.

The total thickness of the barrier layer is preferably 200 nm or less, preferably 100 nm or less, in particular 50 nm or less. Such layers can be preferably formed by atomic layer deposition (ALD), compared to chemical vapour deposition (CVD) with less accurate film and thicker film required, provided that the substrate is smooth enough to receive and sustain the thin film. For example, one or more of the polymers listed above may provide a surface smooth enough.

According to one embodiment, the barrier layer is formed by plasma-assisted atomic layer controlled deposition (PAALD) or metal organic atomic layer deposition (MOALD).

According to one embodiment, the thin film is formed of any metal or metal oxide which can be deposited using ALD. According to a particular embodiment, the film comprises or consists of amorphous aluminum oxide (Al₂O₃). The film may even comprise two or more sub-films lying on the other. The sub-films can be of similar or different thicknesses (e.g. 1-250 nm, preferably 5-100 nm, in particular 5-50 nm).

Alternatively or in addition to Al₂O₃, the thin film may comprise an oxide of a metalloid, such as silicon oxide (SiOₓ), and/or some other material such as B₂O₃ TiO₂, ZrO₂, HfO₂, Ta₂O₅, Nb₂O₅, MgO, CeO₂SiO₂, La₂O₃, SrTiO₃, BaTiO₃, In₂O₃, SnO₂, ZnO, Ga₂O₃WO₃, NiO, MnOₓ, LaCoO₃, LaNiO₃, LaMnO₃, Si, B, Ge, Cu, Mo, Ta or W formed by ALD.

According to a particularly advantageous embodiment, the substrate is a paper or board coated with biopolymer and one or more amorphous aluminum oxide (Al₂O₃) films of thicknesses 20 nm or less.

The invention provides significant advantages. A thin film barrier layer acts as a nanodiffusion layer, decreasing the permeability of the material for vapour and aroma compounds typically by a factor of 10-1000, as compared with a product without such barrier layer. Of particular importance is the decrease in the oxygen and water vapour diffusion rates, which was found to be significant even with a very thin, for example 5-50 nm thick, inorganic barrier layers. Thus, the gas and vapour permeability of biopolymers can be decreased while maintaining the otherwise excellent environmental aspects of the product. In particular when a cellulosic biopolymer-coated substrate is used, the material as a whole is fully recyclable, biodegradable in the environment and non-toxic.

It has been found that the biopolymer coatings are surprisingly well compatible with atomic layer deposition. That is, they provide not only sufficient adhesion but also smoothness even for conformal, very thin gas tight layers to be deposited. A barrier layer can be formed by ALD onto diverse base materials using the biopolymer coating as an intermediate/interface layer between the substrate and the ALD layer.

Atomic layer deposition is a chemical layer by layer process that can be controlled by the accuracy of as low as 0.1 nm (accuracy typically about 0.3 nm, corresponding to the layer thickness per deposition cycle). Thus, the thickness of the barrier layer can be very accurately adjusted to meet the needs of each particular application. Because of its chemical nature, it also has a high reproducibility compared with physical methods. Thus, ALD can be scaled up to very large area substrates, such as paper or board webs and it generates homogeneous, pinhole free and dense layers, at least in comparison with layers of the same thickness produced with physical plasma CVD processes. It is estimated that an equal level of barrier properties can be achieved with one tenth of the layer thickness when the ALD process is used instead of the CVD. The CVD process produces more pinholes to the formed layer and causes the layer not to fill the layer uniformly and conformally enough with small layer thicknesses. In addition, very thin layers are not even producible by CVD, thus decreasing the recyclability of products with a CVD-produced barrier layer. In contrast to that, ALD layers are pinhole-free and very conformal. Thus, a product deposited using ALD is also distinguishable from those deposited using CVD or any other methods.

As the present product is liquid tight and has good moisture and oxygen protection, it can be used for packaging of food products, such as beverages, cereals, frozen food, ice cream, chocolate, and non-food products, such as drugs, cosmetics, liquid detergents and softeners. As the present barrier, in particular when formed using Al₂O₃, provides enhanced oxygen and moisture protection, it can be used also in long shelf life packages of more sensitive products such as beverages, coffee, spices, snacks, cereals and chocolate. In combination with an opaque substrate and/or biopolymer coating, also good light protection is achieved.

Further embodiments and advantages of the invention are described in the following detailed description with reference to the attached drawings.

### BRIEF DESCRIPTION OF DRAWINGS

FIG. 1 shows a schematic (not in scale) cross-sectional view of the product according to one embodiment of the invention.

FIG. 2 shows a schematic (not in scale) cross-sectional view of the product according to another embodiment of the invention.

FIG. 3 shows microscope images of the surface of a coated paper before and after deposition of a 900 nm thick Al₂O₃ barrier layer.

### DETAILED DESCRIPTION OF EMBODIMENTS

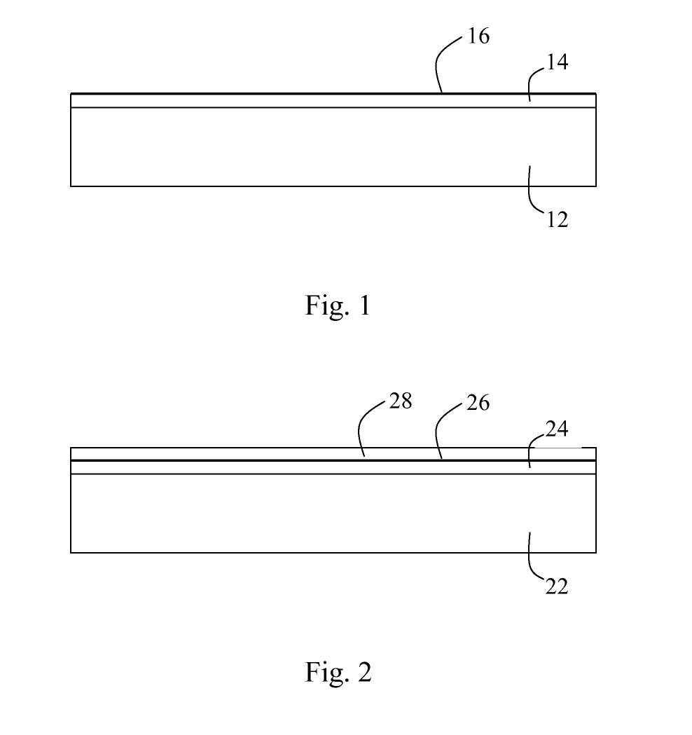

FIG. 1 shows the basic elements of the product according to one embodiment of the invention. The product comprises a fibrous substrate 12, a coating layer 14 applied onto the substrate 12, a thin barrier layer 16 further applied onto the coating layer 14, and a coating layer applied onto the thin barrier layer. Each of the four layers may be comprised of one, two or more distinguishable sub-layers. For example, the substrate 12 may be a single-layer or multi-layer paper and/or board and the coating 14 can be a single coating or multilayer coating.

The substrate is preferably a paper or board formed from cellulosic material, that is, fibres separated from plants, in particular from wooden plants by using mechanical, chemical or chemomechanical pulping.

The substrate may be coated, prior to coating with the biopolymer-containing coating, with pigment or dispersion coating primarily for increasing the smoothness of the substrate. Such a precoating layer allows the use of thinner biopolymer coating at least in cases where a large thickness of the latter is not required for other reasons, such as barrier properties. Application methods and various compositions of pigment and dispersion coatings are known per se and not discussed widely herein. In principle, any coating layer having a smoothness higher than the fiber matrix as such and compatible with the biopolymer(s) used can be utilized.

The substrate is coated using a biopolymer coating or a superposition of such coatings. Biopolymer-containing coatings have been found to meet the requirements of recyclability and/or disposability and suitability for the atomic layer deposition. In addition, biopolymers reinforce and improve the convertibility of the product and typically also contribute to the barrier properties of the product.

The polymer of a polymeric coating can selected from, but not limited to, polysaccharides including starch and derivatives (treated by either plastization, blending with other materials, genetic or chemical modification or combinations of the above approaches), cellulose and derivatives (carboxy-methyl cellulose, methyl cellulose, ethyl cellulose, hydroxyethyl cellulose, hydroxypropyl cellulose and cellulose acetate, micro fibrillated cellulose) and hemicelluloses and chitosan and their derivates, polyphenols from plant origin (lignin, tannin) and their derivatives, lipids, and proteins from plant origin (e.g. gluten, soy, pea and potato) and from animal origin (e.g. casein, whey, collagen, keratin), poly(hydroxyalkanoates) (PHAs) including poly(hydroxybutyrate) and various copolymers, biodegradable polyesters, polyamides and polyurethanes including polylactic acid (PLA), poly(butylsuccinate), poly(butylsuccinate adipate), poly(butylene adipate terephthalate), poly(methylene adipate terephthalate) polycaprolactone (PCL), castor oil urethanes, other aliphatic/aromatic biodegradable copolyesters, biodegradable polyols and polycarbonates, polyanhydrides and polyphosphazenes.

The coating layer may further comprise pigment particles, in particular selected from the group consisting of gypsum, silicate particles, talc particles, plastic pigment particles, clay particles, mica particles, calcium carbonate particles, bentonite particles, alumina trihydrate particles, titanium dioxide particles, phyllosilicate particles, synthetic silica particles, organic pigment particles and mixtures thereof.

The coating layer may further comprise one or more additional components selected from the group consisting of antifoaming agents and salts, defoaming agents and salts, biocides and preservatives, surface tension agents, water retention agents, rheology modifiers, dispersing agents, plasticising agents, lubricants, optical brightening agents, colouring agents, cross-linkers, waxes, volatile alkalis and hydrophobic agents.

According to one embodiment, the biopolymer coating layer is a dispersion comprising a first (bio)polymer and one or more biopolymers selected from biodegradable polyols, such as poly(vinyl alcohol), biodegradable polycarbonates, such as poly(ester carbonate) and biodegradable polyanhydrides and biodegradable polyphosphazenes, and optionally one or more softeners and/or one or more fillers.

The grammage of the coating typically varies from 1 g/m² to 60 g/m². The coating may be applied by any coating method suitable for the particular coating composition known in the paper industry per se.

As discussed above, the inorganic barrier layer typically comprises at least one metal, metalloid or oxide thereof, which is grown on the substrate by the ALD method.

According to one embodiment, the barrier layer consists of an essentially uniform layer formed of one metal, metalloid or oxide thereof grown by the ALD method.

According to another embodiment, the barrier layer comprises at least two metals, metalloids or oxides thereof intermixed or arranged in sub-layers. In a multilayer barrier structure, the different sub-layers may provide different kinds of barrier properties to the product. For example, one sub-layer may be designed primarily for decreasing in particular moisture permeability, whereas another sub-layer may provide a significant decrease in oxygen permeability. By these solutions, the resilience, electrical properties or selectivity to various compounds of the barrier layer can be affected. The different sub-layers may comprise for example Al₂O₃, SiO₂, TiO₂, ZrO₂, ZnO or B₂O₃. Naturally, deposition of the same material as several distinguishable layers is also possible.

FIG. 2 shows a modified product. It comprises a substrate 22, a biopolymer coating 24 and a barrier layer 26 similarly to as described above, and an additional coating layer 28 on the barrier layer. According to one embodiment, the second coating layer 28 comprises of similar components as the first coating layer 24 discussed above with reference to layer 14 of FIG. 1. However, the second coating layer 28 may also be different in composition to reach functional properties required, such as sealability, and protection against wear. The second coating layer 28 may provide enhanced adhesion properties to enable gluing of the product for example when manufacturing a package. According to one embodiment, the second coating layer forms the surface layer of the product.

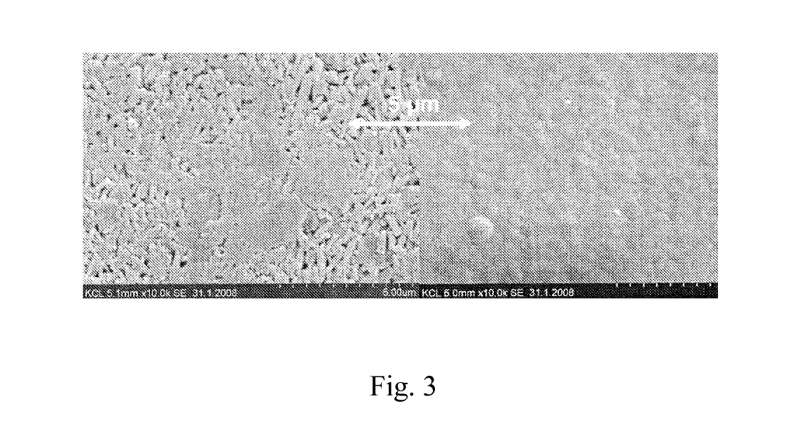

FIG. 3 shows a pigment coated paper before (on the left) and after (on the right) deposition of a 900 nm thick Al₂O₃ barrier layer deposited using ALD. As can be seen from the figure, the topography of the surface does not have a substantial effect on the resulting surface. That is, the barrier layer is nearly complete as it overlays or fills both the micropores (<1 μm) and the macropores (>1 μm) of the substrate.

In general, if a very uniform and pinhole free barrier layer is desired, it is preferable that the thickness of the barrier layer is at least 50% of the maximum pore size on the surface of the substrate or the surface of the coating on the substrate. In particular polymeric coatings provide a sufficiently low porosity so as to allow the atomic layer deposition of layers having a thickness less than 50 nm. The total costs and manufacturing time of the product can be kept competitive compared with the known products providing comparable barrier properties.

Atomic layer deposition is a process well known to skilled persons and not as such discussed herein extensively. Instead, we refer to Ritala M and Leskelä M., Atomic layer deposition in Handbook of Thin Films, 2002, pp. 103-159; Leskelä M. et al J. Materials Science and Engineering: C, 27 (2007), 1504, Exploitation of atomic layer deposition for nanostructured materials and Puurunen, R. L. J., Appl. phys. 97 (2005), pp. 1-52. General principles of depositing inorganic film on an organic polymer using ALD are discussed in US 2004/0194691.

As concerns ALD processing as such also U.S. Pat. No. 7,311,946 can also be referred to. The publication discloses a process providing a surface of the diffusion barrier layer that is substantially free of an elemental metal and forming the metal film on at least a portion of the surface via deposition by using an organometallic precursor.

The growth rate and properties of atomic layer deposited Al₂O₃ thin films were examined in Thin Solid Films Volume 368, Issue 1, 1 Jun. 2000 by varying the water dose in the Al(CH₃)₃—H₂O process. The PAALD method for deposition of Al₂O₃ layers is discussed in J. Appl. Phys. Vol. 40 (2001)285-289. The moisture and vapour permeability properties of Al₂O₃ layers when used in electronic devices are discussed in Appl. Phys. Lett. 86, 223503 (2005) and Appl. Phys. Lett. 89, 081915 (2006). The relevant contents of the above mentioned publications are incorporated herein by reference.

According to one embodiment, the product comprises
a paper or board substrate,
a polymeric coating layer on at least one surface of the fibrous substrate, and
a barrier layer deposited using atomic layer deposition on the coating layer, with the barrier layer having a thickness of less than 1 micrometer and being capable of decreasing water vapour and/or oxygen permeability of the fibrous product at least by 50%, in particular by 90%.

According to a further embodiment, the fibrous product comprises
a paper or board substrate,
a biopolymer-containing coating applied on at least one surface of the substrate, and
metal-oxide barrier layer having a thickness less than 100 nm deposited on the biopolymer coating.

In particular, the substrate may be board or paper, making the product well suitable for rigid and flexible packaging applications. In such applications, the free surface of the substrate, i.e., the surface not containing the inorganic barrier layer, may comprise one or more coating layers and/or printing layers and/or varnish layers.

The invention is further illustrated by the following non-limiting examples:

### Examples

Al₂O₃ was deposited by using ALD on polymer coated boards and papers, and on plain polymer films. The samples include polylactic acid film and paperboard coated with PLA. Both are typical biopolymer applications. The substrates are presented in TABLE 1.

TABLE 1
Substrate characteristics.

| Abbreviation | Description |
|---|---|
| S | Pigment coated and calendered paper |
| P | Polyethylene (LDPE) coated board |
| O | Polylactic acid (PLA) coated board |
| PEN | Polyethylene naphthalene film |
| C | Polypropylene film |
| DI | Dispersion coated board |
| SE | Baking base paper |
| K | Polyethylene (LDPE) coated paper |
| L | Polylactic acid (PLA) film |
| M | Polyester film |

ALD-Al₂O₃ thin films of different thickness were deposited using a commercial ALD TFS 500 reactor manufactured by Beneq Ltd., Finland. The ALD precursors for alumina coatings were trimethylaluminium (TMA) and water. The prepared alumina layer thicknesses were 5, 25, 50 and 100 nm. The coating thicknesses were produced according TFS 500 reactor process parameters with an accuracy of ±0.5 nm and were referred to the thickness of alumina on a silicon wafer. The film growth rate was estimated to be ca. 0.1 nm for TMA-H₂O. All the samples were masked so the ALD deposition of alumina was only on one side of the substrates.

Oxygen transmission rate, OTR, was measured with Mocon OXTRAN equipment and expressed as cm³/m²/d. This computer controlled system utilizes a patented coulometric sensor to detect oxygen transmission through both flat materials and packages. The measurements were done at room temperature (23° C.) at 50-60% relative humidity.

Water vapour transmission rate, WVTR, was measured from flat samples (modified ISO 2528:1995 and SCAN P 22:68). Unhydrous calcium chloride was used as a desiccant. Aluminium dish containing the desiccant is sealed with the sample. As the water vapour penetrates the sample the weight of the dish increases. WVTR is the constant rate of weight increase and it is expressed as g/m²/d. Test conditions were 23° C. and 75% relative humidity with the treated side facing the higher humidity.

KCL AromaBar was used for evaluating the aroma barrier properties. The test cell is divided into aroma source and receiving cells. The test specimen is placed between these cells. The small gaseous samples are automatically removed from cells and analyzed with gas chromatograph. The aroma concentration in the receiving cell is followed as a function of time while compounds diffuse from the source cell containing a model aroma solution through the material. A diluted blend of four aromas serve as the model solutions providing low enough and more realistic vapor concentrations. The diffusion coefficients are determined from the concentration curves by using a non-linear regression analysis.

### Oxygen Barrier:

The oxygen transmission rates are shown in table 2. Even without being optimized, the ALD treatment improved the oxygen barrier of the tested materials, including that of the PLA coated paperboard. Too thick layer causes cracking of the thin layer, which in turn will impair the barrier properties. The value for pigment coated sample was high (>20000 cm³/m²/d)—even when the Al₂O₃ layer thickness was ca. 900 nm. In this case the substrate surface contains pores not totally filled even with a thick ALD alumina layer. This is shown in FIG. 3: Scanning Electron Microscope pictures of a) reference sample S, b) ca. 900 nm thick Al₂O₃ ALD layer on sample S.

TABLE 2
OTR (cm³/m²/day) versus Al₂O₃ layer thickness.

| Sample | reference | 25 nm | 50 nm |
|---|---|---|---|
| P | >20.000 | 6650 | 818 |
| O | 3150 | 49 | 121 |
| C | 1250 | 170 | 109 |
| L | 315 | 44 | 32 |
| M | 24 | 11 | 12 |
| S | >20000 | >20000 | >20000 |

### Water Vapour Barrier:

The water vapour transmission rate (WVTR) values are shown in table 3. Similarly to the OTR, the positive effect of a very thin Al₂O₃ layer on the WVTR is evident. Especially PLA coated board (O) and PLA film (L) experienced a large improvement in the WVTR.

TABLE 3
Effect of Al₂O₃ thickness on WVTR (g/m²/d).

| Sample | reference | 50 nm |
|---|---|---|
| P | 8.5 | 4.6 |
| O | 131 | 14 |
| L | 93 | 3.3 |
| K | 5.4 | 3.1 |
| PEN | 0.9 | 0.6 |

### Aroma Barrier:

As an additional example, table 4 provides the diffusion coefficients of four aroma compounds for polyethylene coated paper as such and after ALD treatment.

TABLE 4
Diffusion coefficients (10⁻¹⁵ m²/s) for reference sample K as
such and same with a 50 nm Al₂O₃ ALD layer.

| Aroma | Reference | 50 nm |
|---|---|---|
| Isoamyl | 9.1 | 3.6 |
| Limonene | 15.8 | 8.7 |
| Hexanol | 7.6 | 3.6 |
| Carvone | 9.9 | 5.2 |

1. Fibrous product comprising
a fibrous substrate,
a coating layer on at least one surface of the fibrous substrate, the coating layer comprising biopolymer, and
a barrier layer deposited on the coating layer, the barrier layer having a thickness of less than about 1 micrometer and being capable of providing barrier properties to the fibrous product,
wherein the barrier layer is formed by atomic layer deposition (ALD).

2. The fibrous product according the claim 1, wherein the substrate is a paper or paperboard, preferably a pigment- or dispersion-coated paper or paperboard.

3. The fibrous product according to claim 1, wherein the coating layer comprises or is essentially comprised of one or more biopolymers.

4. The fibrous product according to claim 1, wherein the coating layer comprises a blend of biopolymer and synthetic non-biobased polymer.

5. The fibrous product according to claim 1, wherein the coating layer comprises biopolymer selected from methyl starch, ethyl starch, hydroxyethyl starch, hydroxypropyl starch and other starch derivatives.

6. The fibrous product according to claim 1, wherein the coating layer comprises biopolymer selected from carboxy-methyl cellulose, methyl cellulose, ethyl cellulose, hydroxyethyl cellulose, hydroxypropyl cellulose, microfibrillated cellulose, cellulose acetate and other cellulose derivatives.

7. The fibrous product according to claim 1, wherein the coating layer comprises biopolymer selected from hemicelluloses, chitosan, gum, pectins, alginates, other animal and plant polysaccharides and their derivatives.

8. The fibrous product according to claim 1, wherein the coating layer comprises biopolymer selected from tannin, lignin and their derivatives.

9. The fibrous product according to claim 1, wherein the coating layer comprises biopolymer selected from gluten, soy protein, casein, collagen, keratin, other animal or plant proteins and protein derivatives.

10. The fibrous product according to claim 1, wherein the coating layer comprises poly(hydroxyalkanoate) biopolymers including poly(hydroxybutyrate) and various other copolymers.

11. The fibrous product according to claim 1, wherein the coating layer comprises biopolyesters and biopolyurethanes including polylactic acid (PLA), poly(butylsuccinate), poly(butylsuccinate adipate), poly(butylene adipate terephthalate), poly(methylene adipate terephthalate), polycaprolactone (PCL), castor oil urethanes and other aliphatic/aromatic polyesters, bio-based polyurethanes and polyamides.

12. The fibrous product according to claim 1, wherein the coating layer comprises biopolymer selected from natural waxes, cross-linked clycerides, other lipids and their derivatives.

13. The fibrous product according to claim 1, wherein the coating layer comprises biopolymer selected from biodegradable polyols, such as poly(vinyl alcohol), biodegradable polycarbonates, such as poly(ester carbonate) and biodegradable polyanhydrides and biodegradable polyphosphazenes.

14. The fibrous product according to claim 1, wherein the coating layer further comprises pigment particles, in particular selected from the group consisting of gypsum, silicate particles, talc particles, plastic pigment particles, clay particles, mica particles, calcium carbonate particles, bentonite particles, alumina trihydrate particles, titanium dioxide particles, phyllosilicate particles, synthetic silica particles, organic pigment particles and mixtures thereof.

15. The fibrous product according to claim 1, wherein the coating layer further comprises one or more additional components selected from the group consisting of antifoaming agents and salts, defoaming agents and salts, biocides and preservatives, surface tension agents, water retention agents, rheology modifiers, dispersing agents, plasticising agents, lubricants, optical brightening agents, colouring agents, cross-linkers, waxes, volatile alkalis and hydrophobic agents.

16. The fibrous product according to claim 1, wherein the thickness of the barrier layer is 200 nm or less, preferably 100 nm or less, in particular 50 nm or less.

17. The fibrous product according to claim 1, wherein the barrier layer is formed by metal organic ALD or plasma-enhanced ALD.

18. The fibrous product according to claim 1 wherein the barrier layer comprises or is essentially comprised of metal, metalloid or oxides thereof, such as Al₂O₃ or SiO₂.

19. The fibrous product according to claim 1, wherein the barrier layer comprises at least two superimposed sub-layers, each of which typically having a thickness between 1-250 nm, preferably 5-100 nm, in particular 5-50 nm.

20. The fibrous product according to claim 1, wherein the barrier layer is capable of reducing diffusion, in particular oxygen and water vapour diffusion, through the product to 50% or less, in particular to 10% or less, compared with a corresponding product without the barrier layer.

21. The fibrous product according to claim 1, wherein the barrier layer is formed of material suitable for atomic layer deposition, preferably of inorganic atomic layer depositable material.

22. Use of the product according to claim 1 for packaging food products, such as beverages, coffee, snacks, cereals, frozen food, ice cream, chocolate, or non-food products, such as drugs, liquid detergents and softeners.

23. A method of manufacturing a fibrous product exhibiting barrier properties, comprising
providing a fibrous substrate,
coating the fibrous substrate on at least one side by a biopolymer-comprising layer, and
depositing a barrier layer having a thickness less than 1 micrometer onto the coating layer,
depositing the barrier layer thereon by the atomic layer deposition (ALD) method.

24. The method according to claim 23, comprising using continuous ALD.

25. The method according to claim 23, wherein the deposition comprises performing several deposition cycles in series.

26. The method according to claim 23, wherein the deposition is performed in a single step.

27. The method according to claim 23, comprising using plasma-assisted ALD or metal organic ALD.

28. The method according to claim 23, wherein an inorganic barrier layer, preferably a metal, metalloid or oxides thereof, such as Al₂O₃ or SiO₂, layer is deposited.

29. A product made according to the steps of claim 23.
